(19) United States
(12) Patent Application Publication
(10) Pub. No.: US 2026/0019077 A1
(43) Pub. Date: Jan. 15, 2026

(54) DESKEW CIRCUIT AND METHOD FOR OPERATING THE SAME

(71) Applicant: Taiwan Semiconductor Manufacturing Company, Ltd., Hsinchu (TW)

(72) Inventors: Yu-Jie Huang, Hsinchu (CN); Mu-Shan Lin, Hsinchu (CN)

(73) Assignee: Taiwan Semiconductor Manufacturing Company, Ltd., Hsinchu (TW)

(21) Appl. No.: 18/772,700

(22) Filed: Jul. 15, 2024

(51) Int. Cl. H03K 17/687; H04L 7/033

(52) U.S. Cl. CPC H03K 17/6872; H04L 7/0331

(57) ABSTRACT

A circuit includes one or more de-skew stages. Each of the one or more de-skew stages is configured to adjust a transition edge of a signal and includes a single inverter, a header configured to couple a first supply voltage to the single inverter, a footer configured to couple a second supply voltage to the single inverter, a capacitor coupled to an output of the single inverter, and a switch circuit coupled between the output of the single inverter and the capacitor.

### BACKGROUND

There are various types of 3D/2.5D integrated circuit (IC) interface. For example, Universal Chiplet Interconnect Express (UCIe) may be one kind of interface standard that can support up to 32 Gb/s data rate. Such high-speed interfaces may include a de-skew circuit to ensure the synchronization and alignment of signals within the interface.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of an example circuit, in accordance with some embodiments.

FIG. 1B is a schematic diagram of an example waveform associated with the circuit of FIG. 1A, in accordance with some embodiments.

FIG. 1C is a schematic diagram of an example waveform associated with the circuit of FIG. 1A, in accordance with some embodiments.

FIG. 2 is a schematic diagram of an example circuit, in accordance with some embodiments.

FIG. 3 is a schematic diagram of an example circuit, in accordance with some embodiments.

FIG. 4 is a schematic diagram of an example circuit, in accordance with some embodiments.

FIG. 5 is a schematic diagram of an example circuit, in accordance with some embodiments.

FIG. 6 is a schematic diagram of an example circuit, in accordance with some embodiments.

FIG. 7 is a flow chart of an example method for operating a circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, a per-lane de-skew circuit is a component of IC interfaces, such as the Universal Chiplet Interconnect Express (UCIe) interfaces, to ensure that the data lane-to-lane skew meets tolerance requirements for different speeds, for example, with a maximum de-skew step resolution of 16 mUI. The design specifications, including correction range and resolution, may vary depending on the operating data rate. To achieve a wider correction range while maintaining fine resolution, additional tuning stages may be added. For example, de-skew stage units can be cascaded to extend the correction range for lower-speed applications. To achieve a k×tuning range, k×stage units can be cascaded. However, this comes with a significant cost in terms of power and area, which could be unacceptable for high-performance and power-efficient UCIe interface designs. For the above example of the cascaded k×stage units, the cost in terms of power and area is at least k time higher. Moreover, such a design that does not implement the techniques disclosed herein may not have enough rise/fall time, which can cause inter-symbol interference (ISI).

The techniques disclosed herein provide a circuit including one or more de-skew stages. Each of the one or more de-skew stages can be configured to adjust a transition edge of a signal based on a first supply voltage coupled with a header and a second supply voltage coupled with a footer. In some embodiments, each of the one or more de-skew stages can include an inverter having an input and an output. The input can be configured to receive a signal and the output can be configured to provide an updated version of the signal with an adjusted transition edge, based on the first supply voltage coupled with the header and the second supply voltage coupled with the footer. In some embodiments, the header can selectively couple the first supply voltage to the inverter, and the footer can selectively couple the second supply voltage to the inverter. In some embodiments, a capacitor can be coupled to the output of the inverter, and a switch circuit can be coupled between the output of the inverter and the capacitor. In some embodiments, the techniques disclosed herein can include use of additional structures for speed control driving to extend the tuning range. For example, driver units such as speed-control adjustable drivers can be added. A Process Voltage Temperature (PVT) calibration structure or circuit can be additionally coupled. Additional switch units, such as transmission gate switches, can be added.

The techniques disclosed herein can enable an adaptive de-skew circuit for various speed data link (e.g., various data rates; 4/8/12/16/24/32 Gb/s) in IC interfaces (e.g., UCIe interface). The techniques allow the de-skew circuit to support different data rate operation requirements and achieve an improved tuning efficiency (e.g., at least two times) and finer resolution, while attaining power and area reduction (e.g., improved Power, Performance, and area (PPA). Furthermore, for lower speed operation applications, the techniques disclosed herein can allow for slower rise/fall time without causing the ISI issues. In addition, by incorporating the PVT calibration structure or circuit, issues caused by PVT variation can be prevented. The techniques disclosed herein provides innovative yet simple and cost-effective solutions for designing an adaptive de-skew circuit in receivers and/or transmitters. In some embodiments, the techniques disclosed herein can be used for other applications, including but not limited to, various die-to-die interfaces such as 3D IC applications, bandwidth on wafer (BoW), advanced interconnect bridge (AIB), high bandwidth memory (HBM), etc.

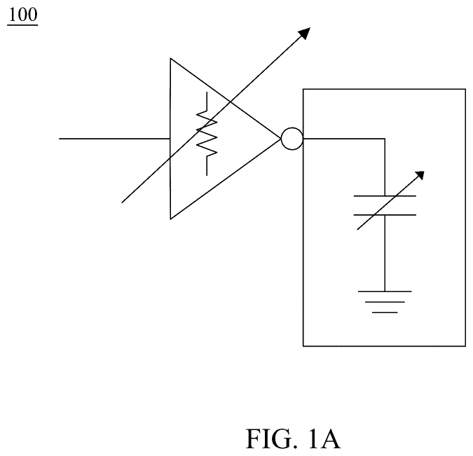

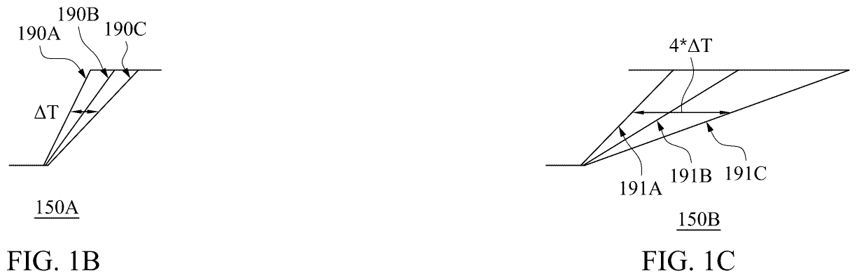

FIG. 1A is a schematic diagram of an example circuit 100, in accordance with some embodiments. In some embodiments, the circuit 100 may be a circuit component or a stage. For example, the circuit 100 may be or include one or more de-skew stages. The circuit 100 can include circuit components, including but not limited to, an inverter, a header, a footer, a capacitor, a switch circuit, etc. Shown in FIG. 1 is a non-limiting example of the circuit 100. In some embodiments, the circuit 100 can include more, fewer, or different components than shown in or described with respect to FIG. 1.

In some embodiments, the circuit 100 includes a single inverter, a header configured to couple a first supply voltage to the single inverter, a footer configured to couple a second supply voltage to the single inverter, a capacitor coupled to an output of the single inverter, and a switch circuit coupled between the output of the single inverter and the capacitor. In some embodiments, the circuit 100 can be included in a data lane of at least one of a transmitter or a receiver. The circuit 100 can include an inverter having an input and an output, and the inverter can be configured such that the input receives a signal and the output provides an updated version of the signal with an adjusted transition edge. The circuit 100 can include a header configured to selectively couple a first supply voltage to the inverter, a footer configured to selectively couple a second supply voltage to the inverter, a capacitor coupled to the output of the inverter, and a switch circuit coupled between the output of the inverter and the capacitor.

The circuit 100 can be configured to adjust a transition edge of a signal. FIG. 1B is a schematic diagram of an example waveform associated with the circuit 100 of FIG. 1A, in accordance with some embodiments. FIG. 1C is a schematic diagram of an example waveform associated with the circuit 100 of FIG. 1A, in accordance with some embodiments. More specifically, FIG. 1B illustrates a signal 150A that the circuit 100 can output with an adjusted transition edge for high speed operation, and FIG. 1C illustrates a signal 150B that the circuit 100 can output with an adjusted transition edge for low speed operation. As shown in FIG. 1B, the circuit 100 can adjust the transition edge of the signal 150A with a tuning range of ΔT. As shown in FIG. 1C, the circuit 100 can adjust the transition edge of the signal 150B with a tuning range of 4×ΔT.

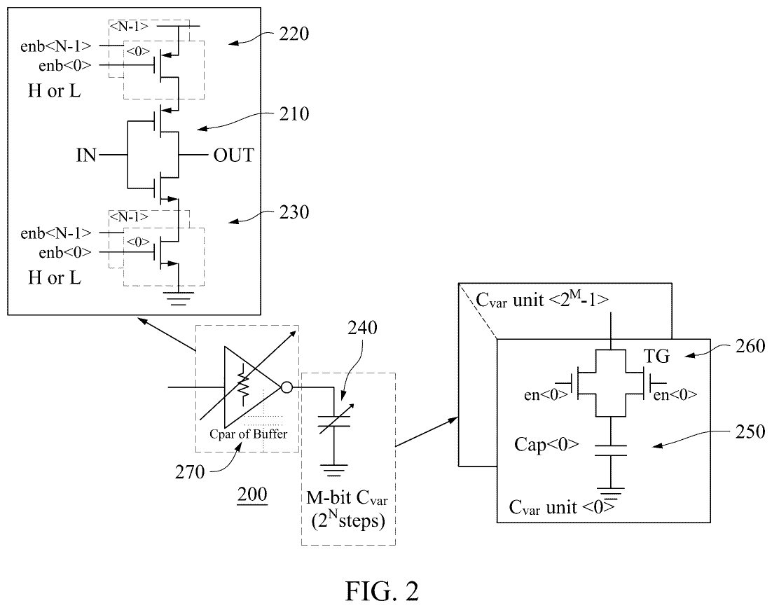

FIG. 2 is a schematic diagram of an example circuit 200, in accordance with some embodiments. In some embodiments, the circuit 200 may be substantially similar to or incorporate features of the circuit 100. In some embodiments, the circuit 200 includes an inverter 210, a header 220, a footer 230, and a variable capacitor 240. In some embodiments, the variable capacitor 240 can include a capacitor 250 and a switch circuit 260. Shown in FIG. 2 is a non-limiting example of the circuit 200. In some embodiments, the circuit 200 can include more, fewer, or different components than shown in or described with respect to FIG. 2.

In some embodiments, the circuit 200 may be a de-skew stage configured to adjust a transition edge of a signal. The circuit 200 can include a single inverter, such as the inverter 210. The inverter 210 can include an input IN configured to receive a signal (e.g., a logic state, a voltage therefor, etc.). The inverter 210 can include an output OUT configured to provide an updated version of the signal with an adjusted transition edge. In some embodiments, as shown in FIG. 2, the inverter 210 can be coupled with the header 220 and the footer 230 such that the header 220 and the footer 230 can provide a supply voltage. In some embodiments, the inverter 210 can output the updated version of the signal based on the supply voltage from at least one of the header 220 and the footer 230. In some embodiments, the inverter 210 can include a semiconductor device, such as a metal-oxide-semiconductor (MOS) transistor. For example, the inverter 210 can include an n-type MOS (NMOS) transistor and a p-type MOS (PMOS) transistor.

The circuit 200 can include the header 220. The header 220 can be configured to couple a first supply voltage to the inverter 210. In some embodiments, the first supply voltage may be a positive voltage rail (VDD). In some embodiments, the header 220 can include N PMOS transistors. In some embodiments, the header 220 can selectively couple the first supply voltage to the inverter 210. For example, a first number of the coupled N PMOS transistors can be in a logic high state, “H,” while a second number of the coupled N PMOS transistors can be in a logic low state, “L.” In some examples, the header 220 can selectively couple the first supply voltage to the inverter 210 based at least in part on the signal that the input IN receives. For example, a first number in the N PMOS transistors of the header 220 can be turned on, the first number determined based on the signal that input IN receives.

The circuit 200 can include the footer 230. The footer 230 can be configured to couple a second supply voltage to the inverter 210. In some embodiments, the second supply voltage may be a ground reference (GND) or a reference point for voltage levels in the circuit 200. In some embodiments, the footer 230 can include N NMOS transistors. In some embodiments, the footer 230 can selectively couple the second supply voltage to the inverter 210. For example, a first number of the coupled N NMOS transistors can be in a logic high state, “H,” while a second number of the coupled N NMOS transistors can be in a logic low state, “L.” In some examples, the footer 230 can selectively couple the second supply voltage to the inverter 210 based at least in part on the signal that the input IN receives. For example, a second number in the N NMOS transistors of the footer 230 can be turned on, the second number determined based on the signal that input IN receives.

In some embodiments, the header 220 and the footer 230 can be alternately turned on. For example, the N PMOS transistors of the header 220 and the N NMOS transistors of the footer 230 can be alternately turned on. The inverter 210 can be configured to couple with the first supply voltage from the N PMOS transistors of the header 220 and the second supply voltage from the N NMOS transistors of the footer 230 alternately. In some embodiments, a first number of the PMOS transistors of the header 220 to be turned on and a second number of the NMOS transistors of the footer 230 to be turned on can be the same. For example, a same number of the PMOS transistors of the header 220 and of the NMOS transistors of the footer 230 can be in a logic high state “H” (and/or in a logic low state “L”). In some embodiments, the first number and the second number can correspond to an adjustment range of the transition edge of the signal. For example, a tuning range of the transition edge of the signal can be greater when the first number and the second number are larger (or smaller). In some embodiments, when a first number of the PMOS transistors of the header 220 and of the NMOS transistors of the footer 230 are in a logic high state, the circuit 200 can provide an updated version of the signal with a first adjusted transition edge (e.g., a first edge 190A in FIG. 1B or a first edge 191A in FIG. 1C). When a second number of the PMOS transistors of the header 220 and of the NMOS transistors of the footer 230 are in a logic high state, the circuit 200 can provide an updated version of the signal with a second adjusted transition edge (e.g., a second edge 190B in FIG. 1B or a second edge 191B in FIG. 1C). When a third number of the PMOS transistors of the header 220 and of the NMOS transistors of the footer 230 are in a logic high state, the circuit 200 can provide an updated version of the signal with a third adjusted transition edge (e.g., a third edge 190C in FIG. 1C or a third edge 191C in FIG. 1C). In some embodiments, the header 220 and the footer 230 can be programmed, programmable, and/or reconfigurable to allow for various ranges of the adjusted transition edge. For example, with the programmable header 220 and footer 230, the de-skew buffer driving strength can be adjusted depending on the speed requirement.

The circuit 200 can include the variable capacitor 240 coupled to the output OUT of the inverter 210. In some embodiments, the variable capacitor 240 can include a MOS capacitor, a passive capacitor, or a combination thereof. For example, the variable capacitor 240 can include the capacitor 250, which can be or include a MOS capacitor, a passive capacitor, or a combination thereof.

In some embodiments, the variable capacitor 240 can include the switch circuit 260. In some embodiments, the switch circuit 260 can be coupled between the output of the inverter 210 and the capacitor 250. In some embodiments, the switch circuit 260 can include or be configured to serve as a transmission gate. For example, the variable capacitor 240 can include 2^{M} variable capacitors 240, and the switch circuit 260 can include 2^{M} transmission gates, when the header 220 includes the N PMOS transistors, and/or the footer 230 includes the N NMOS transistors. In some embodiments, the switch circuit 260 (and/or the transmission gates) can include a MOS transistor. For example, the switch circuit 260 can include a PMOS transistor and a NMOS transistor. This can enable an improved capacitor charging/discharging efficiency, thereby allowing sufficient rise/fall time. In some embodiments, a number of the transmission gates to be activated corresponds to an adjustment resolution of the transition edge of the signal. For example, the circuit 200 can be configured to adjust the transition edge of the signal with an adjustment resolution corresponding to a number of the transmission gates. In some embodiments, when a transmission gate is activated, the gate conducts and allows a signal (e.g., the output of the inverter 210) to pass through. When the transmission gate is deactivated, the gate can block the signal. In some embodiments, the switch circuit 260 can be configured to adjust a delay and/or skew of the output signal from the inverter 210. In some embodiments, the switch circuit 260 (and/or the transmission gates) can be configured to adjust a timing of the signals by selectively introducing delays. For example, by selectively enabling or disabling gates, the timing of the signal passing through the switch circuit 260 can be adjusted. In some embodiments, each of transmission gates in the switch circuit 260 can be configured to introduce a different amount of delay, thereby fine-tuning the timing of the signals with high precision (e.g., finer resolution).

In some embodiments, the circuit 200 can be coupled with or include a capacitor connected with or included in a buffer circuit 270. In some embodiments, the buffer circuit 270 can provide impedance matching, signal amplification, etc. without changing a logic level of an output (e.g., the updated version of the signal) of the inverter 210. For example, the buffer circuit 270 can filter noise, enhance signal stability, etc.

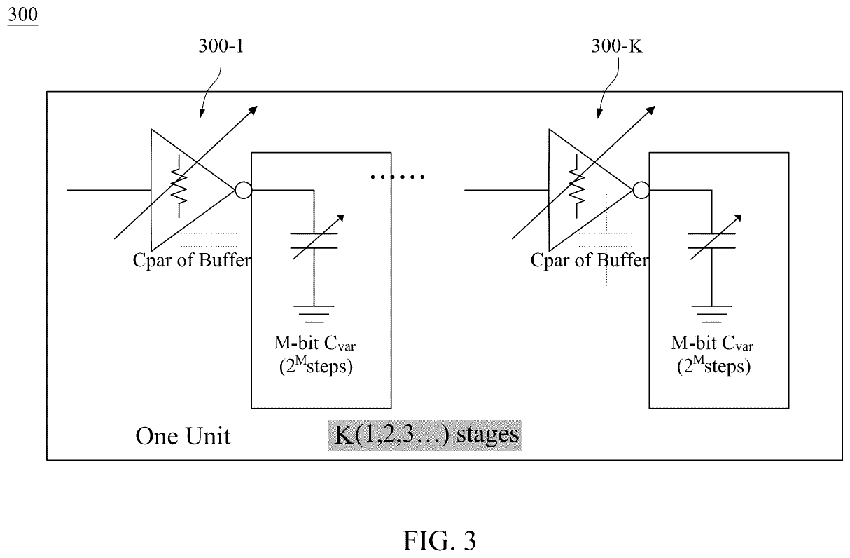

FIG. 3 is a schematic diagram of an example circuit 300, in accordance with some embodiments. The circuit 300 can include a first circuit 300-1, . . . , an k-th circuit 300-K, where m can be any integer. In some embodiments, each of the first circuit 300-1, . . . , the k-th circuit 300-K can be substantially similar to or incorporate features of the circuit 100, the circuit 200, etc. In some embodiments, each of the first circuit 300-1, . . . , the k-th circuit 300-K can be configured to adjust a transition edge of a signal. Shown in FIG. 3 is a non-limiting example of the circuit 300. In some embodiments, the circuit 300 can include more, fewer, or different components than shown in or described with respect to FIG. 3.

By incorporating multiple stage units, for example, the first circuit 300-1, . . . , the k-th circuit 300-K, the design difficulty in meeting the requirement for an improved speed de-skew tuning range can be relaxed. In some embodiments, the same speed adjustment can be applied in each of the first circuit 300-1, . . . , the k-th circuit 300-K to achieve a wider correction range during lower-speed operation without causing ISI issues. For example, to avoid the ISI issues at 32 Gb/s, the multiple stage units (e.g., the first circuit 300-1, . . . , the k-th circuit 300-K) can be incorporated to obtain sufficient rise/fall time while satisfying the minimum correction range (e.g., K×2^{M} steps) requirement at the 32 Gb/s design.

In some embodiments, as shown in FIG. 3, the first circuit 300-1, . . . , the k-th circuit 300-K can be included in one unit circuit, one unit stage (e.g., a de-skew stage), etc. In some embodiments, the first circuit 300-1, . . . , the k-th circuit 300-K can be connected and/or coupled to each other in series, in parallel, or in a combination thereof. In some embodiments, each of the first circuit 300-1, . . . , the k-th circuit 300-K can be configured to adjust a transition edge of a signal in a corresponding circuit, stage, etc. In some embodiments, each of the first circuit 300-1, . . . , the k-th circuit 300-K can be configured to provide different adjustment of transition edge. For example, a first number of MOS transistors can be activated in the first circuit 300-1, while a second number of MOS transistors can be activated in the k-th circuit 300-K. Based on the coupled circuits (e.g., the first circuit 300-1, . . . , the k-th circuit 300-K), an output signal of the circuit can be modulated in various manners.

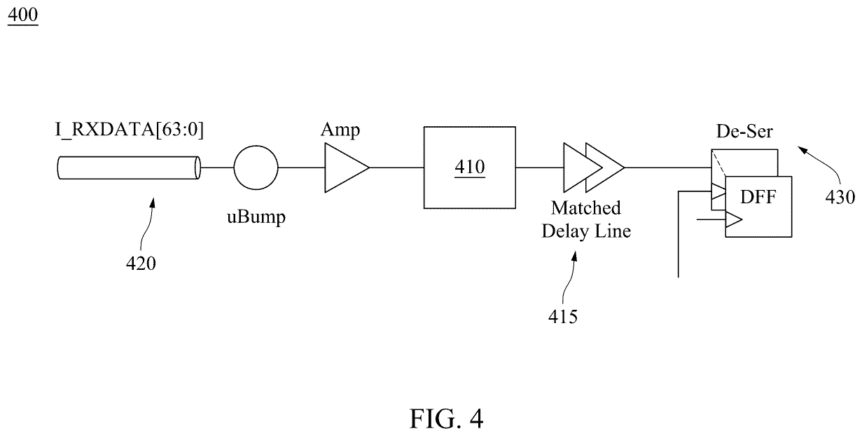

FIG. 4 is a schematic diagram of an example circuit 400, in accordance with some embodiments. More specifically, the circuit 400 can be a receiver circuit. In some embodiments, the circuit 400 is a UCIe receiver. The circuit 400 can include various components, including but not limited to, a data lane 420 (e.g., I_RXDATA[63:0]), a bump structure (e.g., uBump), an amplifier, a circuit 410, a matched delay line 415, a D flip-flop (DFF), and a de-serializer 430, etc. In some embodiments, the circuit 410 can be substantially similar to or incorporate features of the circuit 100, the circuit 200, the circuit 300, etc. That is, the de-skew circuits disclosed herein (e.g., the circuit 100, the circuit 200, the circuit 300, etc.) can be included in a receiver. As shown in FIG. 4, in some embodiments, one or more de-skew stages (e.g., included in the circuit 410 or the circuit 410) can be included in the circuit 400 and operatively coupled between the data lane 420 and the de-serializer 430. In some embodiments, the circuit 410 can be configured to adjust a transition edge of a signal in the circuit 400. For example, the circuit 410 can receive a signal from the data lane 420 as an input, and provide the de-serializer 430 with an updated version of the signal with an adjusted transition edge. In some embodiments, the circuit 410 can provide the updated version of the signal to the matched delay line 415, which can insert a delay line in the data path to match the clock path delay. Shown in FIG. 4 is a non-limiting example of the circuit 400. In some embodiments, the circuit 400 can include more, fewer, or different components than shown in or described with respect to FIG. 4.

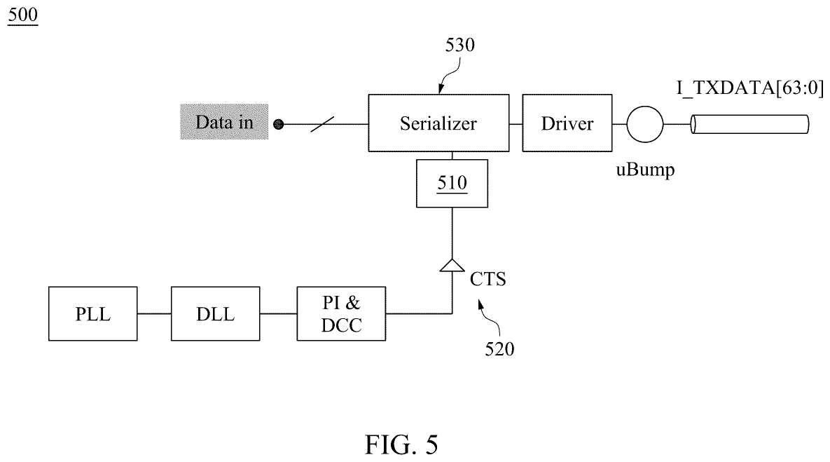

FIG. 5 is a schematic diagram of an example circuit 500, in accordance with some embodiments. More specifically, the circuit 500 can be a transmitter circuit. In some embodiments, the circuit 500 is a UCIe transmitter. The circuit 500 can include various components, including but not limited to, a serializer 530, a driver, a bump structure (e.g., uBump), a data lane (e.g., I_TXDATA[63:0]), a circuit 510, a clock tree 520, etc. In some embodiments, the clock tree 520 can include clock tree synthesis (CTS), a phase interpolator (PI) & a digital clock manager (DCC), a delay locked loop (DLL), a phase locked loop (PLL), etc. In some embodiments, the circuit 510 can be substantially similar to or incorporate features of the circuit 100, the circuit 200, the circuit 300, etc. That is, the de-skew circuits disclosed herein (e.g., the circuit 100, the circuit 200, the circuit 300, etc.) can be included in a transmitter. As shown in FIG. 5, in some embodiments, one or more de-skew stages (e.g., included in the circuit 510 or the circuit 510) can be included in the circuit 500 and operatively coupled between the serializer 530 and the clock tree 520. In some embodiments, the circuit 510 can be configured to adjust a transition edge of a signal in the circuit 500. For example, the circuit 510 can receive a signal from the clock tree 520 as an input, and provide the serializer 530 with an updated version of the signal with an adjusted transition edge. Shown in FIG. 5 is a non-limiting example of the circuit 500. In some embodiments, the circuit 500 can include more, fewer, or different components than shown in or described with respect to FIG. 5.

In some embodiments, the de-skew circuits disclosed herein (e.g., the circuit 100, the circuit 200, the circuit 300, etc.) can be included in a corresponding one of a plurality of data lanes operatively interposed between a transmitter and a receiver. For example, the circuit can receive a signal from the transmitter as an input, and provide the receiver with an updated version of the signal with an adjusted transition edge. By interposing the circuit as such and aligning the timing characteristics, the compatibility between the transmitter and receiver can be improved. For example, the circuit interposed therebetween can enable effective communication between the transmitter and the receiver even with different timing requirements or capabilities.

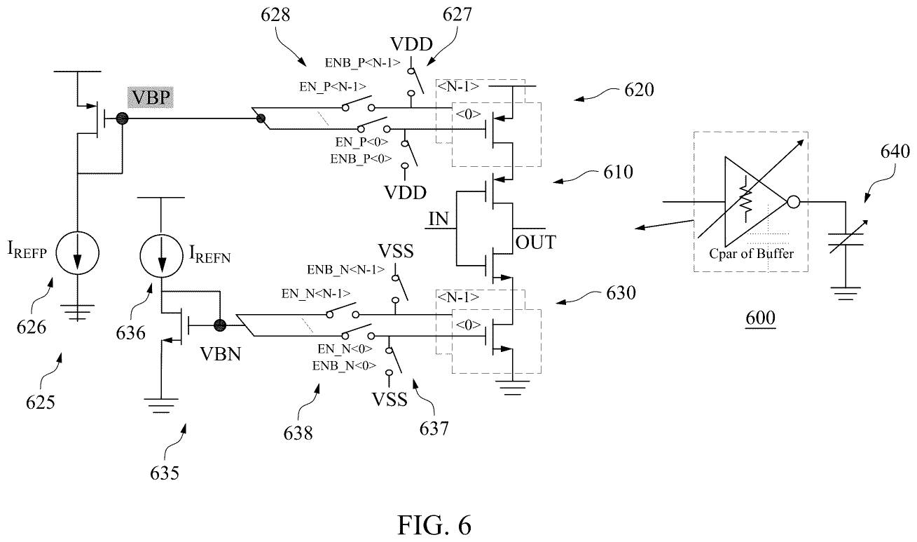

FIG. 6 is a schematic diagram of an example circuit 600, in accordance with some embodiments. The circuit 600 includes an inverter 610, a header 620, a footer 630, and a variable capacitor 640. In some embodiments, the circuit 600 may be substantially similar to or incorporate features of the circuit 200, etc. For example, the inverter 610, the header 620, the footer 630, and the variable capacitor 640 may be substantially similar to or incorporate features of the inverter 210, the header 220, the footer 230, and the variable capacitor 240, respectively. In some embodiments, the circuit 600 can additionally include a first calibration circuit 625 and a second calibration circuit 635. For example, the first calibration circuit 625 can be included in or coupled with the header 620. The second calibration circuit 635 can be included in or coupled with the footer 630. Shown in FIG. 6 is a non-limiting example of the circuit 600. In some embodiments, the circuit 600 can include more, fewer, or different components than shown in or described with respect to FIG. 6.

In some embodiments, the header 620 can be coupled with or include a first current source 626 (e.g., I_{REFP}), N first switches 627 each configured to selectively couple the first supply voltage (e.g., VDD) to the header 620, and N second switches 628 each configured to selectively couple the first current source 626 to the header 620. In some embodiments, when the header 620 includes N PMOS transistors (e.g., <0>, . . . , <N−1>), each of the N first switches 627 (e.g., ENB_P<0>, . . . , ENB_P<N−1>) can selectively couple the first supply voltage to a corresponding one of the PMOS transistors, and each of the N second switches 628 (e.g., EN_P<0>, . . . , EN_P<N−1>) can selectively couple the first current source 626 to a corresponding one of the PMOS transistors.

In some embodiments, the footer 630 can be coupled with or include a second current source 636 (e.g., I_{REFN}), N first switches 637 each configured to selectively couple the second supply voltage (e.g., VSS) to the footer 630, and N second switches 638 each configured to selectively couple the second current source 636 to the footer 630. In some embodiments, when the footer 630 includes N NMOS transistors (e.g., <0>, . . . , <N−1>), each of the N first switches 637 (e.g., ENB_N<0>, . . . , ENB_N<N−1>) can selectively couple the second supply voltage to a corresponding one of the NMOS transistors, and each of the N second switches 638 (e.g., EN_N<0>, . . . , EN_N<N−1>) can selectively couple the second current source 636 to a corresponding one of the NMOS transistors.

In some embodiments, the first current source 626 can provide a current source, I_{REFP}, and the second current source 636 can provide a current source, I_{REFN}, such that a constant current biasing (e.g., I_{REFN}/I_{REFP}) can be provided to the circuit 600. For example, I_{REFP} and I_{REFN} may be constant. This allows for the driver strength to be immune to PVT variation.

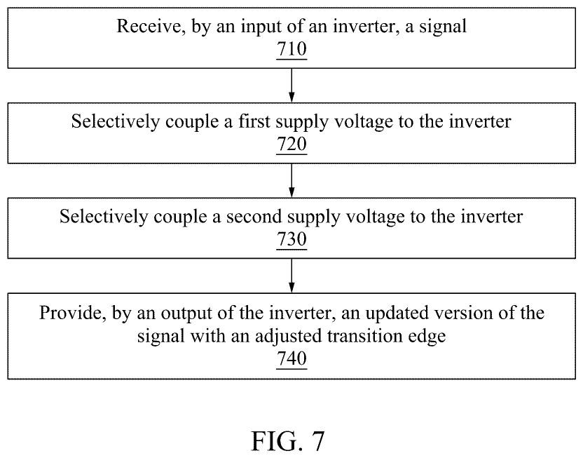

FIG. 7 is a flow chart of an example method 700 for operating a circuit, in accordance with some embodiments. The method 700 may be performed by one or more components of the circuits 100, 200, 300, 400, 500, 600, etc. In some embodiments, the method 700 is performed by other entities. In some embodiments, the method 700 includes more, fewer, or different operations than shown in FIG. 7.

In a brief overview, the method 700 can start with operation 710 of receiving, by an input of an inverter, a signal. The method 700 can continue to operation 720 of selectively coupling a first supply voltage to the inverter. The method 700 can continue to operation 730 of selectively coupling a second supply voltage to the inverter. The method 700 can continue to operation 740 of providing, by an output of the inverter, an updated version of the signal with an adjusted transition edge.

The method 700 can start with operation 710 of receiving, by an input of an inverter, a signal. At operation 710, the inverter (e.g., the inverter 210) can receive a signal through an input of the inverter. In some embodiments, the inverter is part of one or more de-skew stages included in a receiver (e.g., the circuit 400). In some embodiments, the inverter is part of one or more de-skew stages included in a transmitter (e.g., the circuit 500).

The method 700 can continue to operation 720 of selectively coupling a first supply voltage to the inverter. At operation 720, a header (e.g., the header 220) can couple a first supply voltage to the inverter. The method 700 can perform at the same time, or continue to operation 730 of selectively coupling a second supply voltage to the inverter. At operation 730, a footer (e.g., the footer 230) can couple a second supply voltage to the inverter. In some embodiments, the method 700 can include turning on a first number of p-type metal-oxide-semiconductor (PMOS) transistors to selectively couple the first supply voltage to the inverter, and turning on a second number of n-type metal-oxide-semiconductor (NMOS) transistors to selectively couple the second supply voltage to the inverter. In some embodiments, the first number and the second number are the same. In some embodiments, the method 700 can include alternately turning on the PMOS transistors and the NMOS transistors. In some embodiments, a first number of the PMOS transistors to be turned on and a second number of the NMOS transistors to be turned on are the same, both of which can correspond to an adjustment range (e.g., the edges 190A, 190B, and 190C in FIG. 1B, and the edges 191A, 191B, and 191C in FIG. 1C) of the transition edge of the signal.

The method 700 can continue to operation 740 of providing, by an output of the inverter, an updated version (e.g., the signal 150A, the signal 150B, etc.) of the signal with an adjusted transition edge. At operation 740, in some embodiments, the method 700 can include receiving a signal from a data lane (e.g., the data lane 420) of a receiver, and provide a de-serializer (e.g., the de-serializer 430) with an updated version of the signal with an adjusted transition edge. At operation 740, in some embodiments, the method 700 can include receiving a signal from a clock tree (e.g., the clock tree 520) of a transmitter, and provide a serializer (e.g., the serializer 530) with an updated version of the signal with an adjusted transition edge.

In one aspect of the present disclosure, a circuit is disclosed. The circuit includes one or more de-skew stages. Each of the one or more de-skew stages is configured to adjust a transition edge of a signal and includes a single inverter, a header configured to couple a first supply voltage to the single inverter, a footer configured to couple a second supply voltage to the single inverter, a capacitor coupled to an output of the single inverter, and a switch circuit coupled between the output of the single inverter and the capacitor.

In another aspect of the present disclosure, a circuit is disclosed. The circuit includes one or more de-skew stages included in a data lane of at least one of a transmitter or a receiver. Each of the one or more de-skew stages includes an inverter having an input and an output. The input is configured to receive a signal and the output is configured to provide an updated version of the signal with an adjusted transition edge. Each of the one or more de-skew stages includes a header configured to selectively couple a first supply voltage to the inverter, a footer configured to selectively couple a second supply voltage to the inverter, a capacitor coupled to the output of the inverter, and a switch circuit coupled between the output of the inverter and the capacitor.

In yet another aspect of the present disclosure, a method for operating one or more de-skew stages included in a data lane of at least one of a transmitter or a receiver is disclosed. The method includes receiving, by an input of an inverter, a signal, selectively coupling a first supply voltage to the inverter, selectively coupling a second supply voltage to the inverter, and providing, by an output of the inverter, an updated version of the signal with an adjusted transition edge.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
one or more de-skew stages;
wherein each of the one or more de-skew stages is configured to adjust a transition edge of a signal and includes:
a single inverter;
a header configured to couple a first supply voltage to the single inverter;
a footer configured to couple a second supply voltage to the single inverter;
a capacitor coupled to an output of the single inverter; and
a switch circuit coupled between the output of the single inverter and the capacitor.

2. The circuit of claim 1, wherein the header includes N p-type metal-oxide-semiconductor (PMOS) transistors and the footer includes N n-type metal-oxide-semiconductor (NMOS) transistors.

3. The circuit of claim 2, wherein the single inverter is configured to alternately couple with the first supply voltage from the N PMOS transistors and the second supply voltage from the N NMOS transistors.

4. The circuit of claim 3, wherein N corresponds to an adjustment range of the transition edge of the signal.

5. The circuit of claim 1, wherein the switch circuit includes 2^{M} transmission gates.

6. The circuit of claim 5, wherein the each of the one or more de-skew stages is configured to adjust the transition edge of the signal with an adjustment resolution corresponding to a number of the transmission gates.

7. The circuit of claim 1, wherein the one or more de-skew stages are included in a transmitter and operatively coupled between a clock tree and a serializer.

8. The circuit of claim 1, wherein the one or more de-skew stages are included in a receiver and operatively coupled between a data lane and de-serializer.

9. The circuit of claim 1, wherein the one or more de-skew stages are included in a corresponding one of a plurality of data lanes operatively interposed between a transmitter and a receiver.

10. The circuit of claim 1,
wherein the header includes N p-type metal-oxide-semiconductor (PMOS) transistors, a first current source, N first switches each selectively configured to couple the first supply voltage to a corresponding one of the PMOS transistors, and N second switches each configured to selectively couple the first current source to a corresponding one of the PMOS transistors; and
wherein the footer include N n-type metal-oxide-semiconductor (NMOS) transistors and a second current source, N third switches each configured to selectively couple the second supply voltage to a corresponding one of the NMOS transistors, and N fourth switches each configured to selectively couple the second current source to a corresponding one of the NMOS transistors.

11. A circuit, comprising:
one or more de-skew stages included in a data lane of at least one of a transmitter or a receiver;
wherein each of the one or more de-skew stages includes:
an inverter having an input and an output, wherein the input is configured to receive a signal and the output is configured to provide an updated version of the signal with an adjusted transition edge;
a header configured to selectively couple a first supply voltage to the inverter;
a footer configured to selectively couple a second supply voltage to the inverter;
a capacitor coupled to the output of the inverter; and
a switch circuit coupled between the output of the inverter and the capacitor.

12. The circuit of claim 11,
wherein the header includes N p-type metal-oxide-semiconductor (PMOS) transistors and the footer include N n-type metal-oxide-semiconductor (NMOS) transistors, and
wherein the inverter is configured to alternately couple with the first supply voltage from the N PMOS transistors and the second supply voltage from the N NMOS transistors.

13. The circuit of claim 12, wherein N corresponds to an adjustment range of the transition edge of the signal.

14. The circuit of claim 11, wherein the switch circuit includes 2^{M} transmission gates, and wherein the one or more de-skew stages are configured to provide the updated version of the signal with the adjusted transition edge with an adjustment resolution corresponding to a number of the transmission gates.

15. The circuit of claim 11, wherein the one or more de-skew stages are included in the transmitter and operatively coupled between a clock tree and a serializer.

16. The circuit of claim 11, wherein the one or more de-skew stages are included in the receiver and operatively coupled between a data lane and de-serializer.

17. The circuit of claim 11, wherein the one or more de-skew stages are included in a corresponding one a plurality of data lanes operatively interposed between a transmitter and a receiver.

18. A method for operating one or more de-skew stages included in a data lane of at least one of a transmitter or a receiver, the method comprising:
receiving, by an input of an inverter, a signal;
selectively, based at least in part on the signal, coupling a first supply voltage to the inverter;
selectively, based at least in part on the signal, coupling a second supply voltage to the inverter; and
providing, by an output of the inverter, an updated version of the signal with an adjusted transition edge.

19. The method of claim 18, further comprising:
turning on a first number of p-type metal-oxide-semiconductor (PMOS) transistors to selectively couple the first supply voltage to the inverter, the first number determined based on the signal; and
turning on a second number of n-type metal-oxide-semiconductor (NMOS) transistors to selectively couple the second supply voltage to the inverter, the second number determined based on the signal,
wherein the first number and the second number are the same.

20. The method of claim 19, further comprising alternately turning on the PMOS transistors and the NMOS transistors.
